(19) United States
(12) Patent Application Publication
(10) Pub. No.: US 2024/0266922 A1
(43) Pub. Date: Aug. 8, 2024

(54) A COOLING SYSTEM FOR AN INTEGRATED DRIVETRAIN ASSEMBLY AND AN ELECTRIFIED VEHICLE

(71) Applicant: VALEO POWERTRAIN (NANJING) CO., LTD., Jiangsu (CN)

(72) Inventors: Yejin JIN, Jiangsu (CN); Kai CHEN, Jiangsu (CN); Guoqiang SUN, Jiangsu (CN)

(73) Assignee: VALEO POWERTRAIN (NANJING) CO., LTD., Jiangsu (CN)

(21) Appl. No.: 18/566,906

(22) PCT Filed: May 20, 2022
(86) PCT No.: PCT/CN2022/094086

§ 371 Date: Dec. 4, 2023

(30) Foreign Application Priority Data
Jun. 30, 2021 (CN) 202110740761.0

(51) Int. Cl. H02K 9/22; B60K 1/00; B60L 15/00; F16H 57/04; F28F 13/12

(52) U.S. Cl. CPC H02K 9/22; B60L 15/007; F16H 57/0415; F28F 13/12; B60K 2001/006

(57) ABSTRACT

A cooling system includes one cooling circuit configured to flow a coolant and to distribute the coolant at least throughout an integrated drivetrain assembly. The cooling circuit includes a fluid turbulent passage formed by a plurality of cooling spikes and arranged onto an inner surface of a heatsink configured for cooling at least one power switching device provided with the power inverter. The heatsink comprises at least one cooling plate with one corresponding cover, the plurality of cooling spikes are provided on the cooling plate and the corresponding cover. The plurality of cooling spikes include the cooling spikes with an increased or decreased size, the location of the cooling spikes with an increased or decreased size depends on the location of the electrical components provided by the at least one power of switch device so as to modulate the rate and flow of the coolant within the fluid turbulent passage.

### FIELD OF THE INVENTION

Embodiments of the present disclosure relate generally to a cooling system for an integrated drivetrain assembly of an electrified vehicle and an electrified vehicle comprising the cooling system.

### BACKGROUND OF THE INVENTION

The trend towards designing and building fuel efficient, low emission vehicles has increased dramatically, this trend driven by concerns over the environment as well as increasing fuel costs. At the forefront of this trend has been the development of electrified vehicles, such as BEV, HEV, PHEV, Range extended EV, Fuel Cell etc., electrified vehicles that combine a relatively efficient combustion engine with an electric drive motor. Electrified vehicles can include components, particularly the drivetrain system, that generate heat. Excessive heat build-up can cause performance degradation or damage to the components. Specially, cooling solutions for high power electrified vehicles, e.g., for BEV whose power is larger than 30 kW, especially cooling for electronics parts, such as On-board Charger (“OBC”), DC/DC converter and inverter in the drivetrain system would be more complex and the cost would be high.

Therefore, it would be desirable if any improvements on cooling design for the drivetrain system for electrified vehicles could be provided at least with simple configuration, high efficiency and low cost.

### SUMMARY OF THE INVENTION

Aspects and advantages of the invention will be set forth in part in the following description, or may be obvious from the description, or may be learned through practice of the invention.

In accordance with one aspect disclosed herein, a cooling system for an integrated drivetrain assembly of an electrified vehicle is provided. The integrated drivetrain assembly generally comprises an electric motor, a reducer mechanically coupled to the electric motor, and a power inverter at least electrically connected to the electric motor. The cooling system comprises one cooling circuit configured for being flowed through with a coolant and for distributing the coolant at least throughout the integrated drivetrain assembly. The cooling circuit comprises a fluid turbulent passage formed by a plurality of cooling spikes and arranged onto an inner surface of a heatsink configured for cooling at least one power switching device provided with the power inverter. The heatsink comprises at least one cooling plate with one corresponding cover, the plurality of cooling spikes are provided on the cooling plate and the corresponding cover. The plurality of cooling spikes comprise the cooling spikes with an increased or decreased size, the location of the cooling spikes with an increased or decreased size depends on the location of the electrical components provided by the at least one power of switch device so as to modulate the rate and flow of the coolant within the fluid turbulent passage.

In some embodiments, the cooling spikes with an increased or decreased size are provided with either the at least one cooling plate or the corresponding cover.

In some embodiments, the cooling spikes with an increased or decreased size are provided with both the at least one cooling plate and the corresponding cover.

In some embodiments, the increased or decreased size comprises an increased or decreased height, generating variable heights between each free ends of the cooling spikes with an increased or decreased size and the inner surface of the cover or the cooling plate.

In some embodiments, the increased or decreased size further comprises an increased or decreased width, generating variable width between the cooling spikes with an increased or decreased size and the adjacent cooling spikes.

In some embodiments, the cooling spikes with an decreased size are arranged nearby the electrical components where the flow of coolant becomes larger.

In some embodiments, the cooling spikes with an increased size are arranged away from the electrical components in the flow direction of the coolant increasing the fluid velocity.

In some embodiments, the heatsink comprises one cooling plate with one corresponding cover, configured for providing one-side cooling for the at least one power switching device.

In some embodiments, the heatsink comprises at least two cooling plates with at least two corresponding covers, the at least one power switching device is configured to be arranged between each two cooling plates so as to be cooled from dual sides.

In some embodiments, a plurality of cooling fins are arranged onto an outer surface of the heatsink (15) for heat dissipation by convection.

In some embodiments, the coolant is ultra-low viscosity oil.

In accordance with another aspect disclosed herein, an electrified vehicle comprising the cooling system according to the above described is provided.

These and other features, aspects, and advantages of the present disclosure will become better understood with reference to the following detailed description. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 is a schematic view of a cooling system for an integrated drivetrain assembly in accordance with an exemplary aspect of the present disclosure;

FIG. 2 is a schematic view of one exemplary arrangement for the power switching device and a heatsink comprising the cooling spikes with increased and decreased size in accordance with an exemplary aspect of the present disclosure;

FIG. 3 is a schematic view of another exemplary arrangement for the power switching device and a heatsink comprising the cooling spikes with increased and decreased size in accordance with an exemplary aspect of the present disclosure;

### DETAILED DESCRIPTION OF THE INVENTION

Reference will now be made to in detail to present embodiments of the invention, one or more examples of which are illustrated in the accompanying drawings. The detailed description uses numerical and letter designations to refer to features in the drawings. Like or similar designations in the drawings and description have been used to refer to like or similar parts of the invention. As used herein, the terms “a”, “an” and “the” are intended to mean that there are one or more of the elements unless the context clearly dictates otherwise. The terms “comprising”, “including” and “having” are intended to be inclusive and mean that there may be additional elements other than the listed elements.

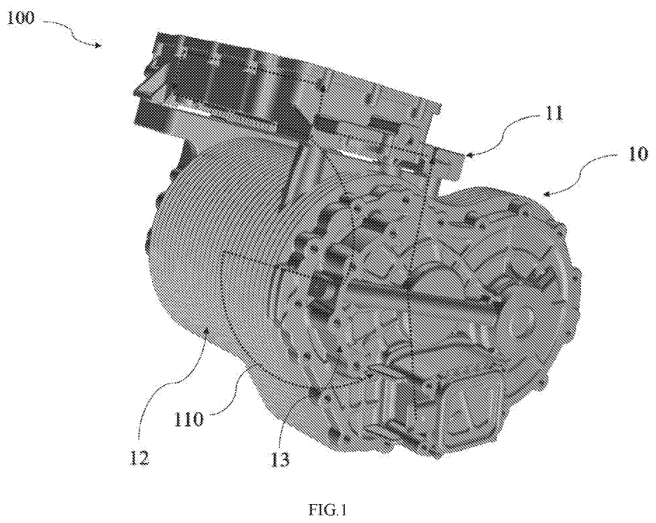

Referring now to the drawings, wherein identical numerals indicate the same elements throughout the figures, FIG. 1 shows a cooling system 100 for an integrated drivetrain assembly 10 in accordance with one embodiment of the present disclosure. The drivetrain assembly 10 is generally integrated with a power inverter 11, an electric motor 12 and a reducer 13. The drivetrain assembly 10 as shown is therefore a single unit.

The electric motor 12 can be a synchronous motor or an asynchronous motor. When it is a synchronous motor, it may include a wound rotor or a permanent magnet rotor. The peak power supplied by the electric motor can be between 10 KW and 80 KW, for example, of the order of 40 KW, for a nominal supply voltage of 48V to 400V, or up to 800V for higher power. In the case of an electric motor adapted to a high voltage supply, the nominal power supplied by this electric motor may be 25 KW. In the illustrated embodiment, the electric motor 12 is a synchronous motor with permanent magnets, providing a peak power between 10 KW and 80 KW. The electric motor 12 can include a stator with a three-phase winding, or a combination of two three-phase windings or five-phase windings.

The reducer 13 is mechanically coupled to the electric motor 12. The reducer 13 can transform the electric motor's high speed, low torque to low speed, high torque. The reducer 13 may comprise two or more gears, with one of the gears driven by the electric motor 12 for instance, for torque increase via speed reduction. The reducer may further comprise a transmission shaft, i.e., an intermediate shaft, linking a driving gear driven by one transmission shaft of the electric motor 12 and another gear of larger diameter coupled to a driven mechanical load (not shown, e.g., vehicle wheel shafts).

In the illustrated embodiments, the electric motor 12 and the reducer 13 are designed with high thermal capacity. The power inverter 11 is attached by the electrical wires to the electric motor 12 and mechanically to a wall of the electric motor 12 or to a wall of the reducer 13 or to both walls of the electric motor 12 and the reducer 13. The power inverter 11 converts the direct current (“DC”) supplied by, for example, an integrated power electronics assembly (not shown) providing with the electric energy of a nominal voltage to the alternating current (“AC”) used to the electric motor 12. The power inverter 11 can comprise at least one power switching device 17, such as, field effect transistors (“FETs”), metal oxide semiconductor field effect transistors (“MOSFETs”) or insulated gate bipolar transistors (“IGBTs”). In the case of a nominal supply voltage of 48V, the power switching device 17 can be MOSFET transistors. In the case of a supply voltage corresponding to a high voltage, the power switching device 17 can be IGBTs.

As for the integrated power electronics assembly as mentioned above, it may comprise OBC, and/or DC/DC converter and/or PDU. OBC is generally installed in the BEV and connect to an external power supply. DC/DC converter is a power electronic device that convert the DC input voltage supplied by, e.g., the battery power, to a certain amplitude DC output voltage, which can be applied for all kinds of electrified vehicle, including for BEV. PDU is a high-voltage power supply that distributes the battery power to the high-voltage components of the vehicle. The integrated power electronics assembly can be, for example, electrically connected with the power inverter 11 and mechanically mounted to the power inverter 11. In one embodiment, the integrated power electronics assembly can be, for example, coupled with the integrated drivetrain assembly 10 by tubes.

A cooling system is designed to ensure at least of the temperatures of the integrated drivetrain assembly 10 are maintained with a desired operating ranges when the vehicle is running and at stop, i.e., at a parking phase.

Referring to FIG. 1, the cooling system 100 may include a plurality of cooling fins arranged on an outer surface of a housing containing at least the electric motor 12 and the reducer 13. The plurality of cooling fins may be carried by the outer surface of the housing and are for example made in one piece with the housing. The cooling fins allow to increase the outer surface of the housing, and thus promote the heat dissipation to the outside of the drivetrain assembly 10 via the housing.

The cooling system 100 may further include a cooling circuit 110. The cooling circuit 110 being flowed through with coolant is provided for distributing the coolant throughout the integrated drivetrain assembly 10.

The coolant can be the oil with ultra-low viscosity. The kinetic viscosity value of this kind of ultra-low viscosity oil at 40° C. will be less than 40 and the kinetic viscosity value at 100° C. will be less than 10. By using this kind of ultra-low viscosity oil flowing throughout the integrated drivetrain assembly via the cooling circuit 110, all components contained could be both lubricated and cooled down more efficiently with lower pressure drop.

The oil flowing in the cooling circuit 110 maybe transferred by a pumping device. The pumping device may control the oil flowing through the cooling circuit 110 at a required flow rate, further, may have the oil autonomously flow throughout the cooling circuit 110 for cooling and lubrication during operating, and may circulate the oil through the cooling circuit 110 as well. In one embodiment, the pumping device can be an electrical pump and the OBC may supply power to the electrical pump for operation. The electrical pump will continue to work during the parking phase. In one embodiment, if the OBC is absent, a mechanical pump can be considered to apply in the cooling system. The mechanical pump can be driven by a driving shaft, such as an intermedia shaft, which will work when the vehicle wheel are rotating.

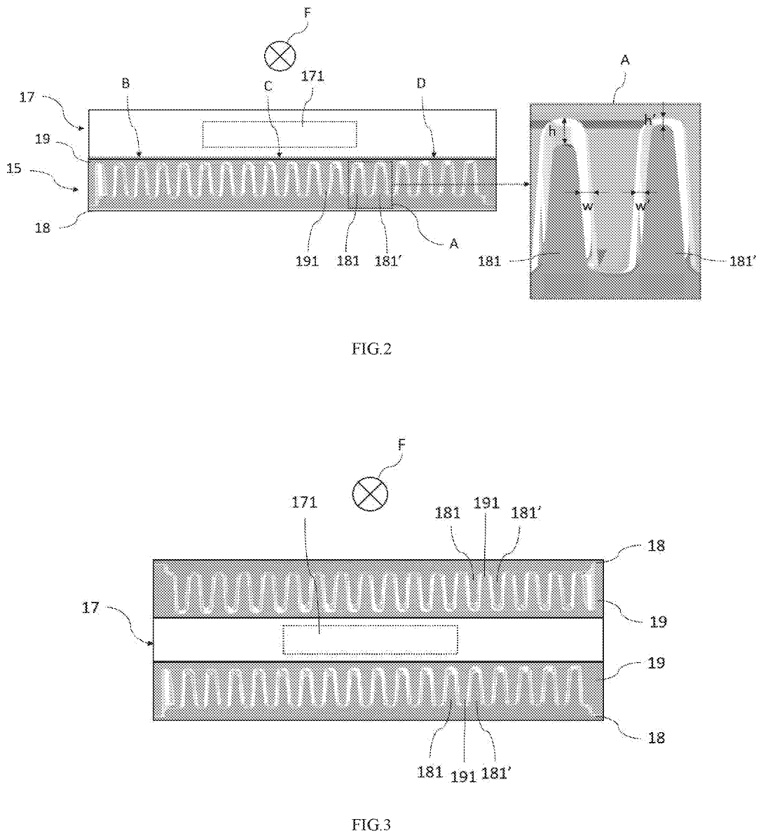

Generally, the oil is firstly transferred from, for example, an electrical pump to the power inverter 11. Regarding the cooling for the power inverter 11, referring to FIG. 2, the cooling circuit 110 can comprise a fluid turbulent passage provided within the power inverter 11. The fluid turbulent passage is particularly formed by a plurality of cooling spikes 191, 181, 181′ arranged onto an inner surface of a heatsink 15 for cooling the power switching device 17, such as IGBTs provided by the power inverter 11. The cooling spikes are made of thermal material, for example aluminum.

As illustrated in FIG. 2, showing an exemplary configuration of the heatsink 15 and the power switching device 17. The heatsink 15 is enclosed by one cooling plate 19 with one corresponding cover 18, the cooling plate 19 and the cover 18 both provide with the cooling spikes 181, 181′, 191. The cooling spikes 191 provided by the cooling plate 19 extend from an inner surface of the cooling plate 19 towards an inner surface of the cover 18, while the cooling spikes 181, 181′ provided by the cover 18 extend from the inner surface of the cover 18 towards the inner surface of the cooling plate 19, so that the cooling spikes 181, 181′ from the cooling plate 18 and the cover 19 are spaced and the flow passage gap among the spikes can be narrowed, that is, the double-sided spike distribution within the heatsink 15 increases the flow velocity around the spikes, improving the cooling performance of the power switching device 17.

Still referring to FIG. 2, the cooling spikes 181, 181′ provided by the cover 18 can be design to have a variable size. For example, the heatsink 15 can be formed to include different portions, for example, a first portion B, a second portion C, a third portion D. In a second portion C, the cooling spikes 181 provided by the cover 18 can have a smaller size, whereas in a first and third portions B, D, the cooling spikes 181′ provided by the cover 18 can have a greater size. The size of the cooling spikes in each portion B, C, D can be designed to provide with variable velocity and amount of the coolant within the fluid turbulent passage formed by the cooling spikes so as to optimize the cooling of the power switching device 17. Particularly, the cooling spikes 181 with an decreased size are arranged nearby the electrical components 171 which always generate heat when operating, i.e., in the second portion C, where the rate of coolant becomes higher and the flow of coolant becomes larger, ensuring enough coolant flow nearby the electrical components 171. The spikes size, for example, the spikes height are growing in the direction F, so that the velocity gets also higher while the fluid temperature increases during the passage of the coolant in the direction F.

Referring to the enlarged portion A, the variable size of the cooling spikes includes variable height h, h′ between each free ends of the cooling spikes 181, 181′ and the inner surface of the cooling plate 19. For example, in the second portion C, the cooling spikes 181 will have a smaller height and the height h between the free ends of the cooling spikes 181 and the inner surface of the cooling plate 19 will be larger, in the meanwhile, in the third portion D, the cooling spikes 181′ will have a larger height and the height h′ between the free ends of the cooling spikes 181′ and the inner surface of the cooling plate 19 will be smaller.

The variable size of the cooling spikes also includes variable width w, w′ between the cooling spikes 181, 181′ from the cover 18 and the adjacent cooling spikes. For example, in the second portion C, the width w between the cooling spikes 181 from the cover 18 and the adjacent cooling spikes is larger, in the meanwhile, in the third portion D, the width w′ between the cooling spikes 181′ from the cover 18 and the adjacent cooling spikes is smaller.

Since the electrical components 171 of the power switching device 17 generate amounts of heat when operating, the cooling spikes nearby the electrical components 171, for example, in the second portion C, are designed to be smaller so as to have sufficient coolant flowing therein for heat dissipation. The spikes height are growing in the direction F, so that the velocity gets also higher while the fluid temperature increases during the passage of the coolant in the direction F.

In one embodiment, the cooling spikes 191 provided by the cooling plate 19 can also have variable sizes, including variable height between the free ends of the cooling spikes 191 and the inner surface of the cover 18, and variable width between the spikes 191 from the cooling plate 19 and the adjacent spikes.

Referring to FIG. 3, showing another exemplary configuration of the heatsink 15 and the power switching device 17. The heatsink 15 can comprise two cooling plates 19 with two corresponding covers 18, the power switching device 17 is arranged between the two cooling plates 19 so as to be cooled from dual sides. The cooling spikes 181, 181′, 191 forming fluid turbulent passages within the heatsink 15 can have variable sizes, which will optimize the cooling of the power switching device 17. The cooling spikes 181 with smaller sizes are for example arranged nearby the electrical components 171 of the power switching device so as to allow sufficient coolant flowing therein. The spikes height are growing in the direction F, so that the velocity gets also higher while the fluid temperature increases during the passage of the coolant in the direction F.

In one embodiment, a plurality of cooling fins can be further arranged onto an outer surface of the heatsink 15 for heat dissipation by convection. Ambient air, as well as the air from a fan, may flow through these cooling fins to achieve a desired cooling.

The present disclosure also provides an electrified vehicle having the cooling system according to the foregoing.

This written description uses examples to disclose the embodiments of the present disclosure, including the best mode, and also to enable any person skilled in the art to practice embodiments of the present disclosure, including making and using any devices or systems and performing any incorporated methods. The patentable scope of the embodiments described herein is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A cooling system for an integrated drivetrain assembly of an electrified vehicle, the integrated drivetrain assembly comprising an electric motor, a reducer mechanically coupled to the electric motor, and a power inverter at least electrically connected to the electric motor, the cooling system comprising
one cooling circuit configured for being flowed through with a coolant and for distributing the coolant at least throughout the integrated drivetrain assembly, the cooling circuit comprising a fluid turbulent passage at least formed by a plurality of cooling spikes and arranged onto an inner surface of a heatsink which is configured for cooling at least one power switching device provided with the power inverter,
wherein the heatsink comprises at least one cooling plate with one corresponding cover, the plurality of cooling spikes are provided on the at least one cooling plate and the corresponding cover, the plurality of cooling spikes comprising the cooling spikes with an increased or decreased size, the location of the cooling spikes with an increased or decreased size depends on the location of the electrical components provided by the at least one power of switch device so as to modulate the rate and flow of the coolant within the fluid turbulent passage.

2. The cooling system according to claim 1, wherein
the cooling spikes with an increased or decreased size are provided with either the at least one cooling plate or the corresponding cover, or
the cooling spikes with an increased or decreased size are provided with both the at least one cooling plate and the corresponding cover.

3. The cooling system according to claim 2, wherein
the increased or decreased size comprises an increased or decreased height, generating variable heights between each free ends of the cooling spikes with an increased or decreased size and the inner surface of the cover or the cooling plate.

4. The cooling system according to claim 2, wherein
the increased or decreased size further comprises an increased or decreased width, generating variable width between the cooling spikes with an increased or decreased size and the adjacent cooling spikes.

5. The cooling system according to claim 1, wherein
the cooling spikes with an decreased size are arranged nearby the electrical components where the flow of coolant becomes larger.

6. The cooling system according to claim 5, wherein
the cooling spikes with an increased size are arranged away from the electrical components in the flow direction of the coolant increasing the fluid velocity.

7. The cooling system according to claim 1, wherein
the heatsink comprises one cooling plate with one corresponding cover, configured for providing one-side cooling for the at least one power switching device, or
the heatsink comprises at least two cooling plates with at least two corresponding covers, the at least one power switching device is configured to be arranged between each two cooling plates so as to be cooled from dual sides.

8. The cooling system according to claim 1, wherein
a plurality of cooling fins are arranged onto an outer surface of the heatsink for heat dissipation by convection.

9. The cooling system according to claim 1, wherein
the coolant is ultra-low viscosity oil.

10. An electrified vehicle, comprising the cooling system according to claim 1.

11. The cooling system according to claim 3, wherein
the increased or decreased size further comprises an increased or decreased width, generating variable width between the cooling spikes with an increased or decreased size and the adjacent cooling spikes.

12. An electrified vehicle, comprising the cooling system according to claim 2.

13. An electrified vehicle, comprising the cooling system according to claim 3.

14. An electrified vehicle, comprising the cooling system according to claim 4.

15. An electrified vehicle, comprising the cooling system according to claim 5.

16. An electrified vehicle, comprising the cooling system according to claim 6.

17. An electrified vehicle, comprising the cooling system according to claim 7.

18. An electrified vehicle, comprising the cooling system according to claim 8.

19. An electrified vehicle, comprising the cooling system according to claim 9.
